(19) United States
(12) Patent Application Publication
(10) Pub. No.: US 2010/0041558 A1
(43) Pub. Date: Feb. 18, 2010

(54) Electromagnetic radiation detection device and manufacturing process thereof

(75) Inventors: Abdelkader Aliane, Grenoble (FR); Thierry Farjot, Le Gua (FR); Claude Pigot, Saint Forget (FR)

Correspondence Address: OLIFF & BERRIDGE, PLC, P.O. BOX 320850, ALEXANDRIA, VA, 22320-4850, US

(73) Assignee: COMMISSARIAT A L'ENERGIE ATOMIQUE, PARIS (FR)

(21) Appl. No.: 12/461,294

(22) Filed: Aug. 6, 2009

(30) Foreign Application Priority Data
Aug. 12, 2008 (FR) 08 04574

(51) Int. Cl. H01L 31/032; H01L 31/18; G01K 13/00; H01L 39/02

(52) U.S. Cl. 505/160; 438/93; 438/54; 374/141; 257/428; 374/E13.001; 257/E31.026; 257/E21.001

(57) ABSTRACT

The electromagnetic radiation detection device comprises at least one absorption membrane for absorbing said radiation. The absorption membrane is formed by an absorption layer made of tungsten nitride (W₂N) and having a stoichiometric ratio tungsten to nitride equal to two.

### TECHNICAL FIELD OF THE INVENTION

The invention refers to an electromagnetic radiation detection device comprising at least one absorption membrane for absorbing said radiation.

### STATE OF THE ART

The electromagnetic radiation detection devices enable to convert the energy of said radiation into heat inside an absorption membrane 1. As illustrated in FIG. 1, the absorption membrane 1 is classically connected to a thermometer 2 by means of an assembly layer 3 enabling the transfer of the temperature.

In the case of an X-radiation detection devices, the X-radiation absorption membranes are either resistive, i.e. the variation of the resistance of the thermometer material depends on the temperature, or superconductive. In order to improve the sensibility of the detection device, the heat capacity of the absorption membrane must be as low as possible. Thus, it is preferable to use superconductive materials having a heat capacity falling to zero under their superconductive transition temperature, i.e. under this temperature the resistance falls to zero.

The detection devices used in astrophysics generally work at very low temperatures, typically from 50 to 100 mK, for detecting X-radiations in the range from 100 eV to 6 keV and up to 30 keV in the field of spatial research.

As known, the absorption membranes based on superconductive materials can be made of an alloy of copper and bismuth (CuBi), or of bismuth and gold. Although these materials have good superconductive properties, they have a relatively low absorption capacity for X-radiations.

X-radiations interact with the material and their absorption depends on the atomic number Z and the density of the used material. Indeed, the higher the atomic number of a material is, the denser and thus the more absorbent the material is. That is why superconductive materials with high atomic numbers Z are used in the realization of X-radiation detection devices. It is for example the case of mercury telluride (HgTe), of rhenium (Re), of iridium (Ir) and of tantalum (Ta).

### OBJECT OF THE INVENTION

The object of the invention is an electromagnetic radiation detection device, for example an X-radiation detection device, with an absorption layer having a high percentage of absorption.

This object is achieved by the appended claims and more particularly by the fact that the absorption membrane is formed by an absorption layer made of tungsten nitride and having a stoichiometric ratio tungsten to nitride equal to two.

The object of the invention is also a manufacturing process of the electromagnetic radiation detection device comprising the following steps of:
depositing a tungsten nitride layer onto a silicon oxide layer covering a first support substrate, said tungsten nitride layer having a stoichiometric ratio tungsten to nitride equal to two,
bonding the tungsten nitride layer onto an adhesive film located on a second support substrate,
eliminating the first support substrate and the silicon oxide layer.

### BRIEF DESCRIPTION OF THE DRAWINGS

Other advantages and characteristics will become more evident from the following description of specific embodiments of the invention given as non-limitative examples and represented in the annexed drawings in which:

FIG. 1 illustrates an electromagnetic detection device according to the prior art.

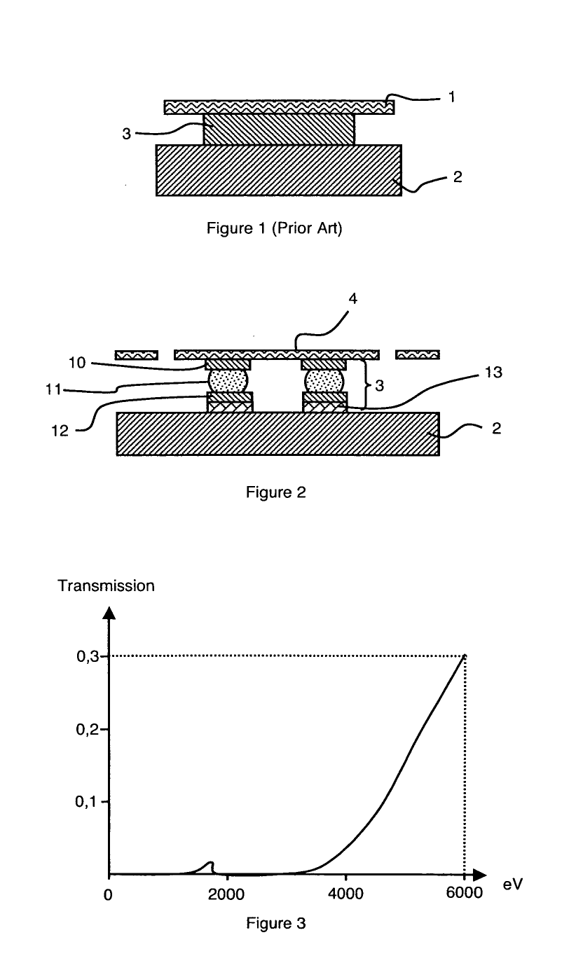

FIG. 2 illustrates a cross-section of a detection device according to the invention.

FIG. 3 represents the transmission curve for X-radiations according to the photonic energy of a tungsten nitride absorption layer.

FIGS. 4 and 5 represent transmission curves for X-radiations according to the photonic energy of absorption layers according to the prior art.

FIGS. 6 to 14 illustrate a manufacturing process for a detection device according to the invention.

### DESCRIPTION OF A SPECIFIC EMBODIMENT

The electromagnetic radiation detection device, for example for an X-radiation, classically comprises at least one pixel provided with an absorption membrane 1 for said radiation and with a thermometer 2 connected to the absorption membrane 1 by means of an assembly layer 3. According to the invention, the absorption membrane 1 is formed by an absorption layer 4 made of tungsten nitride (W₂N) and having a stoichiometric ratio tungsten to nitride W/N equal to two (W/N=2).

Tungsten nitride W₂N is a superconductor having a high transition temperature Tc. Indeed, with a density of about 18 g/cm³, its transition temperature Tc can be of 4.57 K.

It is possible to assess the percentage of X-radiation absorbed by an absorption layer. The radiation transmission can be calculated from the attenuation of the intensity of the X-radiation according to the expression:

$$I = {I}_{0} {exp}^{- ( \frac{μ}{ρ} ) ρ L}$$

where

I₀ is the intensity of the incident flux onto the absorber,

μ/ρ is the mass absorption coefficient in cm².g⁻¹, ρ

ρ is the density of the material constituting the absorber (in g.cm⁻³),

μ is the linear absorption coefficient of the material of the plate forming the absorber (in cm⁻¹),

and L is the thickness of the absorber (in cm).

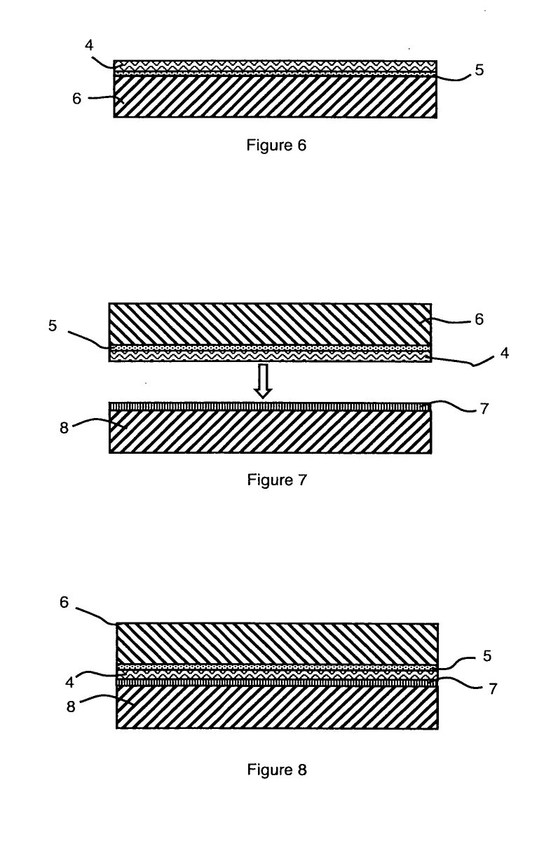

As illustrated in FIG. 3, for an absorption layer with a thickness of 2 μm and a specific density of 17.7, the simulation of the transmission of X-radiations in the range from 100 eV to 6000 eV by a layer made of tungsten nitride (W₂N) gives a value of 0.3 for the transmission at 6000 eV, i.e. an absorption of 70%.

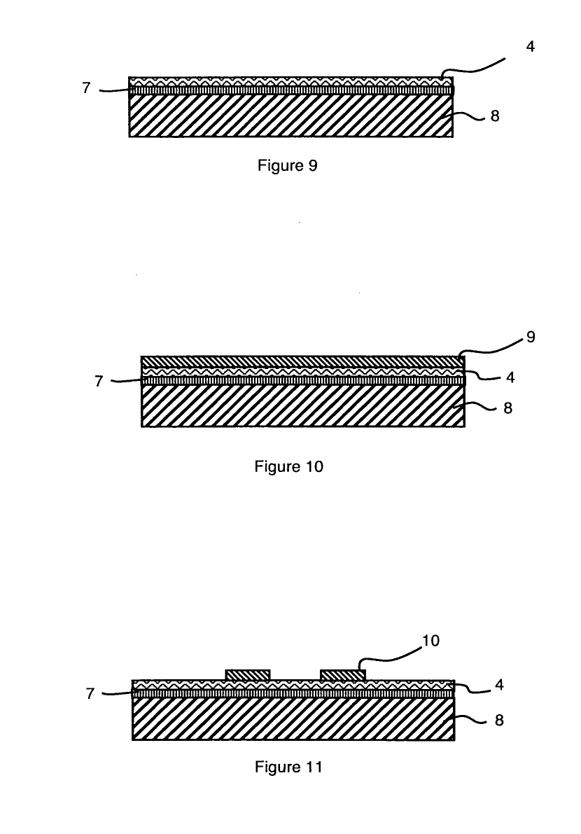

In comparison, FIG. 4 illustrates the same curve for an absorption layer made of mercury tellurite (HgTe) having a thickness of 2 μm and a specific density of 8.09. The simulation of the transmission of X-radiations in the range from 100 eV to 6000 eV for an HgTe layer gives a transmission from 0.44 at 6000 eV, i.e. an absorption of 56%. Moreover, the curve of the transmission according to the photonic energy has parasitic transmission peaks at 2 and 4 keV.

Similarly, FIG. 5 illustrates the simulated transmission curve for tantalum (Ta) with a specific density of 16.654 and an absorption layer thickness of 2 μm. At 6000 eV, the percentage of absorption is 68% (transmission of 0.32).

Thus, the absorption of the X-radiations by tungsten nitride is better than by the known absorption layers made of mercury tellurite or of tantalum.

Moreover, for higher energies (above 6000 eV), the absorption gain of tungsten nitride (W₂N) is superior to that of tantalum if the thickness of the layer made of tungsten nitride W₂N is increased. Preferably, the tungsten nitride layer has a thickness between 0.1 and 10 μm. A thickness of tungsten nitride higher than 10 μm is possible, but does not reduce, or improve, the performances.

Tungsten nitride (W₂N) is however a material difficult to realize in thin layer. Like many nitrides, it is a very constrained material and the realization of a layer with a thickness higher than 1 μm is delicate. Thus, the invention also concerns a process for making this realization easier.

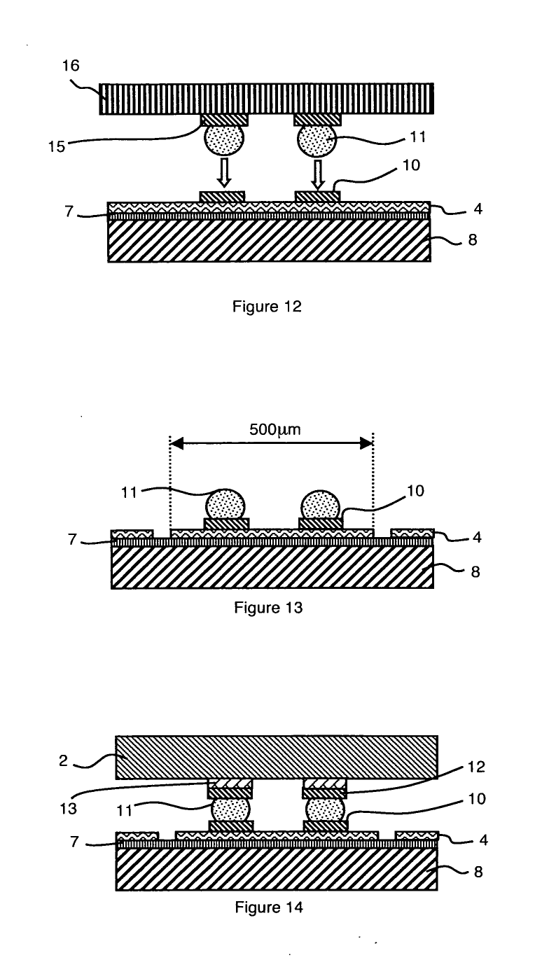

The process described below, with reference to FIGS. 6 to 14, enables to realize a detection device comprising an absorption membrane formed by a thin tungsten nitride (W₂N) layer 4. First, the process includes a step of deposition of a tungsten nitride layer 4 (FIG. 6), preferably with a thickness of 2 μm, onto a silicon oxide layer 5 covering a first support substrate 6. The support substrate 6 can have a thickness of the order of 725 μm and the silicon oxide layer can have a thickness of the order of 500 nm.

The deposition of the tungsten nitride (W₂N) layer 4 is realized, for example, by a PVD process (Physical Vapor Deposition). Thus, the reactive mixture between tungsten and nitride is realized directly inside the deposition chamber. In order to minimize the constraints, the deposition pressure has been modified while maintaining between the neutral gases of the chamber, for example argon (Ar) and nitrogen (N), a constant pressure ratio for maintaining the deposition stoichiometry at two. During the realization, tests enabled to measure a ratio W/N of 2.07 by using a classical analysis of back-scattered electrons (“RBS” for Rutherford Back Scattering). Otherwise, the resistivity of the so-obtained layer is equal to 156 μohms.cm at room temperature.

Then, a double-sided adhesive film 7 is stuck (FIG. 7) onto a second silicon support substrate 8 (FIG. 7). Then, the side of the first support substrate 6 comprising the tungsten nitride layer 4 is stuck onto the free side of the adhesive film 7. The support substrate 8 serves as a silicon handle enabling to handle the tungsten nitride layer without damaging it. Once it is stuck (FIG. 8), the first support substrate 6 and the silicon oxide layer 5 are eliminated, preferably by mechanical and chemical polishing (PCM) so as to free the tungsten nitride layer 4 (FIG. 9).

An assembly layer 3 enabling to connect the tungsten nitride absorber to a thermometer is then realized. Then, the assembly layer 3 and the tungsten nitride layer 4 are structured to form pixels.

For example, the assembly layer 3 realizing the connection between the tungsten nitride absorption layer 4 and the thermometer 2 is made with gold-based and indium-based materials. Preferably, the indium-based material is formed by balls made of indium or an indium alloy. Thus, the step of realization of the assembly layer 3 can comprise the deposition of a thin gold layer 9 (FIG. 10) onto the tungsten nitride layer 4. The thickness of this gold layer 9 is preferably of 150 nm. Then, the gold layer 9 is etched up to the tungsten nitride 4 for forming connection pins 10 on the surface of the tungsten nitride layer 4. Then, an indium ball 11, which is initially instable (FIG. 12), is deposited on each connection pin 10 by means of a support 16 provided with contacts 15 (UBM for “Under Bump Metal”) comprising, for example, a titanium layer having a thickness of 300 nm, in contact with the support 16, and a gold layer having, preferably, a thickness of 70 nm in direct contact with the corresponding indium ball 11. The indium balls are considered as being initially instable because the contact 15 does not comprise much gold and thus has a low wettability. The balls 11 are intended to be used as electrical connection elements. Once the balls 11 are deposited, the gold layer of the connection pins 10, which is thicker than that of the contacts 15, enables to stabilize the indium balls by improving the wettability. Then, the tungsten nitride layer 4 is structured in pixels by simply etching it up to the adhesive film 7, as illustrated in FIG. 13. Preferably, each pixel has the form of a 500 μm-side square. The assembly layer 3 can also be made out of a conductive polymer material such as an epoxy adhesive SU8® connecting the tungsten nitride absorption layer 4 to the thermometer 2.

After the tungsten nitride layer 4, has been structured, a thermometer 2 comprising connection terminals 12 is transferred and hybridized onto the assembly layer 3 of each pixel.

The thermometer can be amorphous or crystalline silicon-based. The thermometer can also be a superconductive transition thermometer (TES for “Transition Edge Sensor”). Such a superconductive transition thermometer can comprise, for example, a titanium layer and a gold layer or a molybdenum layer and a gold layer, the gold layer being then able to directly form the connection terminals 12 in contact with the assembly layer 3.

The connection terminals 12 are arranged on the thermometer 2 so as to face the indium balls 11 during the transfer of the thermometer 2. The connection terminals 12 can be made of gold. Preferably, an element 13 is placed between the connection terminals 12 and the thermometer 2. This element 13 can include a coupling layer (or adhesion layer) in contact with the thermometer and a diffusion barrier layer for the indium placed between the coupling layer and the corresponding connection terminal 12. The coupling layer can be made out of titanium and the diffusion barrier layer can be made out of nickel or palladium.

After the thermometer 2 has been transferred onto the indium balls 11, the thermometer 2 is fixed with the tungsten nitride absorption layer by stabilizing the indium balls in order to form a pixel. The fixation or hybridization of the indium balls is realized by a remelting process. At this time, an intermetallic compound is formed with the gold of the connection pins 10, the indium balls and the gold of the connection terminals 12, thus stabilizing the indium balls.

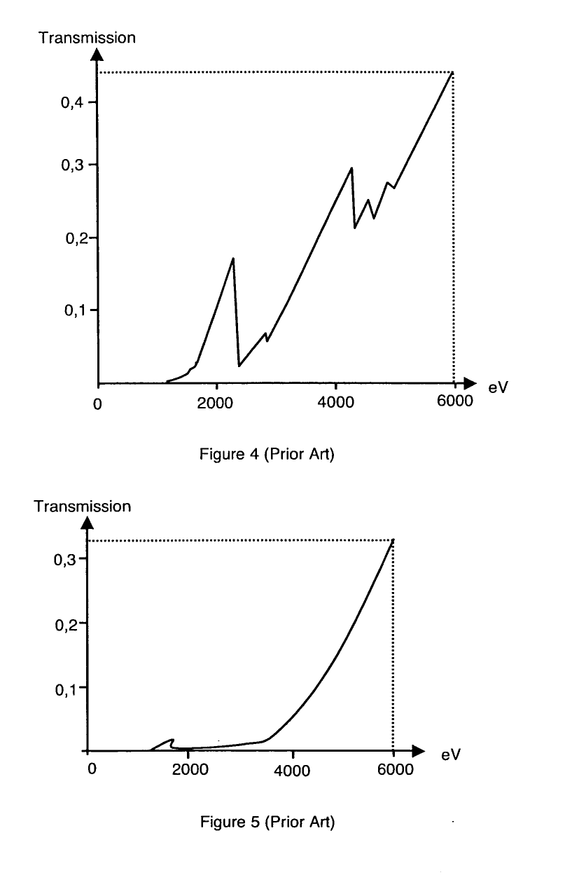

Finally, the second support substrate 8 is removed by dissolution of the adhesive film 7 in a solvent, for example acetone. After the adhesive has been dissolved, the detection device of FIG. 2 is obtained.

Such a device has a very good absorption property for X-radiations. Moreover, tungsten nitride has the advantage that a further treatment is not necessary for using it as a X-radiation absorber.

The obtained device can be used in applications needing a high X-radiation resolution, for example in the field of astronomy, astrophysics, material analysis, neutron physics or dark matter research.

1. An electromagnetic radiation detection device comprising at least one absorption membrane for absorbing said radiation, wherein the absorption membrane is formed by an absorption layer made of tungsten nitride having a stoichiometric ratio tungsten to nitride equal to two.

2. A detection device according to claim 1, wherein the tungsten nitride absorption layer is connected to a thermometer by an assembly layer made of an indium-based material or of a conductive polymer material.

3. A detection device according to claim 2, wherein the thermometer is made of amorphous or crystalline silicon based material.

4. A detection device according to claim 2, wherein the thermometer is a superconductive transition thermometer.

5. A detection device according to claim 4, wherein the superconductive transition thermometer includes a titanium layer in contact with a gold layer, said gold layer being in contact with the assembly layer.

6. A detection device according to claim 1, wherein the tungsten nitride layer has a thickness between 0.1 μm and 10 μm.

7. A manufacturing process for a detection device according to claim 1, including at least the following successive steps of:
depositing a tungsten nitride layer onto a silicon oxide layer covering a first support substrate, said tungsten nitride layer having a stoichiometric ratio tungsten to nitride equal to two,
bonding said tungsten nitride layer onto an adhesive film located on a second support substrate,
eliminating the first support substrate and of silicon oxide layer.

8. A process according to claim 7, then including:
realization of an assembly layer,
structuring the tungsten nitride layer and the assembly layer in pixels,
transferring and hybridization of a thermometer onto the assembly layer of each pixel,
releasing of the pixels in a solvent enabling to dissolve the adhesive film.

9. A process according to claim 8, wherein the realization of the assembly layer includes:
depositing a gold layer onto the tungsten nitride layer,
forming a structure of connection pins in the gold layer,
and transferring of an indium ball, which is initially instable, onto each connection pin.
